(19) United States
(12) Patent Application Publication
(10) Pub. No.: US 2025/0248297 A1
(43) Pub. Date: Jul. 31, 2025

(54) OXAMIDE ULTRAVIOLET ABSORBER-DOPED PEROVSKITE ACTIVE LAYER, PEROVSKITE SOLAR CELL, AND PREPARATION METHODS THEREOF

(71) Applicant: TAIYUAN UNIVERSITY OF TECHNOLOGY, Taiyuan (CN)

(72) Inventors: Yuying HAO, Taiyuan (CN); Dengjie ZHAO, Taiyuan (CN); Chenxi ZHANG, Taiyuan (CN); Shiqi LI, Taiyuan (CN)

(21) Appl. No.: 19/085,577

(22) Filed: Mar. 20, 2025

(30) Foreign Application Priority Data
Mar. 22, 2024 (CN) 202410332190.0

(51) Int. Cl. H10K 85/50; H10K 30/50; H10K 30/81; H10K 30/84; H10K 71/12; H10K 71/60; H10K 102/20

(52) U.S. Cl. CPC H10K 85/50; H10K 30/50; H10K 30/81; H10K 30/84; H10K 71/12; H10K 71/60; H10K 2102/20

(57) ABSTRACT

An oxamide ultraviolet absorber-doped perovskite active layer, including a perovskite film and an oxamide ultraviolet absorber doped therein, where the oxamide ultraviolet absorber is N-(2-ethoxyphenyl)-N′-(2-ethylphenyl) oxamide, and a perovskite structure is represented by ABX₃. A perovskite solar cell, including a conductive substrate layer, a lower interfacial transport layer, the perovskite active layer, an upper interfacial transport layer and a metal electrode arranged sequentially from bottom to top. Methods for preparing the perovskite active layer and the perovskite solar cell are also provided.

### CROSS-REFERENCE TO RELATED APPLICATIONS

This application claims the benefit of priority from Chinese Patent Application No. 202410332190.0, filed on Mar. 22, 2024. The content of the aforementioned application, including any intervening amendments thereto, is incorporated herein by reference in its entirety.

### TECHNICAL FIELD

This application relates to perovskite solar cells, and more particularly to an oxamide ultraviolet absorber-doped perovskite active layer, a perovskite solar cell, and preparation methods thereof.

### BACKGROUND

Perovskite materials, characterized by high light absorption coefficient, long carrier lifetime and controllable direct optical band gap, are widely recognized as the most ideal material for the new-generation solar cell, and the perovskite solar cell technologies have received considerable attention in the research and development of the next-generation photovoltaic technology. In particular, flexible perovskite solar cells have advantages of high power-to-weight ratio, remarkable rollable, bendable and portable characteristics, and continuous roll-to-roll preparation, and have unique application prospects in flexible displays, wearable products and various portable electronic devices.

There are still some bottlenecks in the current perovskite solar cells. The perovskite film, as a perovskite active layer, has poor crystal quality, small crystal particle and excessive grain boundaries, while excessive grain boundaries will bring higher defect density, which will further aggravate the defect-induced carrier recombination, reducing the power conversion efficiency of perovskite solar cells. The energy level of the perovskite active layer and the interfacial transport layer (including an upper interfacial transport layer and a lower interfacial transport layer) are not matched, and a large interface energy barrier will hinder extraction and transportation of carriers. The residual tensile strain of polycrystal perovskite film reduces the formation energy of vacancy defects and the activation energy of ion migration in the perovskite material, which accelerates the degradation of perovskite. External water and oxygen will erode the perovskite through surface and grain boundary defects, resulting in irreversible phase transition and degradation of the perovskite material. In particular, a conductive substrate layer of the flexible perovskite solar cell is an organic polymer, which has poor barrier to water and oxygen, and compared with the rigid cell, the degradation of devices will be aggravated. In addition, continuous light irradiation, especially ultraviolet light irradiation, will cause photoinduced phase transition of perovskite crystal, and even accelerate the erosion by water and oxygen, affecting the long-term stability of the device. The above problems seriously restrict the development of perovskite solar cell.

In the prior art, an addition of oxamide ultraviolet absorber/passivator, such as 2-(2-hydroxy-5-methylphenyl)benzotriazole (UVP), melatonin and cerium oxide, in the perovskite active layer can solve the problem of poor ultraviolet stability, which reduces the damage of ultraviolet to the perovskite material, improving the light stability of the perovskite solar cell. However, reported additives have relatively simple effects, and have no report on whether they can regulate the crystal quality of perovskite and release the residual tensile strain of perovskite and application effects in flexible perovskite solar cell.

Therefore, this application is to develop technical solutions to solve the problems of poor crystal quality of perovskite, many defect states, energy level mismatch between the perovskite active layer and the interfacial transport layer, large residual tensile strain of perovskite film and poor ultraviolet stability of device, which has great significance for development of perovskite solar cell with low-cost, high-efficiency and good stability.

### SUMMARY

This application is to provide a N-(2-ethoxyphenyl)-N′-(2-ethylphenyl) oxamide-doped perovskite active layer, a N-(2-ethoxyphenyl)-N′-(2-ethylphenyl) oxamide-doped perovskite solar cell, and preparation methods thereof.

In other to achieve the above objectives, technical solutions of this application are described as follows.

In a first aspect, this application provides a perovskite active layer, comprising a perovskite film and an oxamide ultraviolet absorber; wherein the oxamide ultraviolet absorber is doped into the perovskite film; and the oxamide ultraviolet absorber is N-(2-ethoxyphenyl)-N′-(2-ethylphenyl) oxamide; and the N-(2-ethoxyphenyl)-N′-(2-ethylphenyl) oxamide has a structure shown as follows:

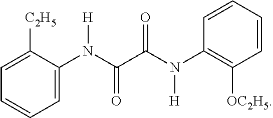 [SMILES: CCOc1ccccc1NC(=O)C(=O)Nc1ccccc1CC]

In an embodiment, the perovskite active film has a perovskite structure represented by ABX₃, wherein A is selected from the group consisting of a cesium ion (Cs⁺), a formamidinium ion (FA⁺), a methylammonium ion (MA⁺) and a combination thereof; B is a lead ion (Pb²⁺); and X is selected from the group consisting of an iodide ion (I⁻), a chloride ion (Cl⁻), a bromide ion (Br⁻) and a combination thereof.

In a second aspect, this application provides a perovskite solar cell, comprising the perovskite active layer above.

In an embodiment, a thickness of the perovskite active layer is 450-600 nm.

In an embodiment, the perovskite solar cell comprises a conductive substrate layer, a lower interfacial transport layer, the perovskite active layer, an upper interfacial transport layer and a metal electrode arranged; wherein the conductive substrate layer, the lower interfacial transport layer, the perovskite active layer, the upper interfacial transport layer and the metal electrode are sequentially arranged from bottom to top.

In an embodiment, the conductive substrate layer comprises a substrate and a conductive material coated thereon; and the substrate is made from a material selected from the group consisting of glass, sapphire, polyethylene terephthalate (PET), polyethylene naphthalate (PEN), polyimide (PI), polycarbonate (PC), polyethersulfone (PES), polydimethylsiloxane (PDMS), thermoplastic polyurethane (TPU), and metal foil; and the conductive material is selected from the group consisting of indium tin oxide (ITO), indium-doped zinc oxide (IZO), aluminum-doped zinc oxide (AZO), fluorine-doped tin oxide (FTO,) a silver nanowire, a composite material composed of the silver nanowire and a two-dimensional material, a carbon-based nanomaterial and a metal mesh.

In an embodiment, the lower interfacial transport layer and the upper interfacial transport layer are each independently made from a material selected from the group consisting of SnO₂, TiO₂, NiOₓ, poly[bis(4-phenyl) (2,4,6-trimethylphenyl)amine] (PTAA), poly(3,4-ethylenedioxythiophene-poly(styrenesulfonate) (PEDOT:PSS), [6,6] phenyl-C₆₁-butyric acid methyl ester (PC₆₁BM), [6,6] phenyl-C₇₁-butyric acid methyl ester (PC₇₁BM), C₆₀, indene-C₆₀ bis-adduct (ICBA), C₇₀, ZnSO₄, CuSCN, CuGaO₂, WOₓ, MoOₓ, Al₂O₃, Nb₂O₅, SiO₂, ZrO₂, 2,2′,7,7′-Tetrakis[N,N-di(4-methoxyphenyl)amino]-9,9′-spirobifluorene (Spiro-OMeTAD), poly(3-hexylthiophene) (P3HT) and a combination thereof.

In an embodiment, the metal electrode is made from a material selected from the group consisting of Au, Ag and Cu.

In a third aspect, this application provides a method for preparing a perovskite active layer, comprising:
(S1) mixing perovskite raw materials and N-(2-ethoxyphenyl)-N′-(2-ethylphenyl) oxamide in a solvent to obtain a perovskite precursor solution;
(S2) coating the perovskite precursor solution on a substrate; and
(S3) subjecting the substrate to annealing treatment to obtain a N-(2-ethoxyphenyl)-N′-(2-ethylphenyl) oxamide-doped perovskite film as the perovskite active layer.

In an embodiment, the perovskite raw materials comprise:
a first material selected from the group consisting of formamidine iodide (FAI), methylammonium iodide (MAI), cesium iodide (CsI) and a combination thereof;
a second material, wherein the second material is lead iodide (PbI₂); and
a third material selected from the group consisting of methylammonium bromide (MABr), methylammonium chloride (MACl), lead bromide (PbBr₂), dimethylammonium iodide (DMAI), formamidine bromide (FABr), cesium chloride (CsCl), cesium bromide (CsBr) and a combination thereof.

In an embodiment, a ratio of Pb²⁺ to N-(2-ethoxyphenyl)-N′-(2-ethylphenyl) oxamide in the perovskite precursor solution is 0.5-2 mol: 0.1-4 mg; preferably, the ratio of Pb²⁺ to N-(2-ethoxyphenyl)-N′-(2-ethylphenyl) oxamide in the perovskite precursor solution is 0.5-2 mol: 0.1-3 mg.

In an embodiment, the solvent is selected from the group consisting of a first solvent and a second solvent; the first solvent is selected from the group consisting of dimethylformamide (DMF), dimethyl sulfoxide (DMSO), N-Methyl-2-pyrrolidone (NMP), gamma-butyrolactone (GBL), acetonitrile (ACN), and a combination thereof; and the second solvent is isopropyl alcohol (IPA).

In an embodiment, the solvent is a mixture of DMF and DMSO, and a volume ratio of DMF to DMSO is 3-20:1, preferably 18-20:1, 8-10:1 or 3-5:1.

In an embodiment, a concentration of Pb²⁺ of in the perovskite precursor solution is 0.01 mol/L-10 mol/L.

In an embodiment, a concentration of N-(2-ethoxyphenyl)-N′-(2-ethylphenyl) oxamide in the perovskite precursor solution is 0.1 mg/mL-4 mg/mL.

In an embodiment, step (S2) is performed through at least one of blade coating, slot-die coating, roll-to-roll coating, spin coating, gravure coating, aerosol coating and inkjet printing.

In an embodiment, the perovskite precursor solution is coated on the substrate through the spin coating, and the spin coating is performed at a rate of 800 rpm-6000 rpm for 5 s-60 s.

In an embodiment, based on the number of the spin coating, the spin coating is divided into one-step spin coating or two-step spin coating.

In an embodiment, the one-step spin coating is performed through coating the perovskite precursor solution on the substrate at one time with or without an addition of an anti-solvent during the one-step spin coating, followed by annealing treatment to obtain the perovskite active layer.

In an embodiment, the anti-solvent is selected from the group consisting of chlorobenzene, ethanol, isopropanol, methylbenzene, tetrahydrofuran, acetonitrile, ether, ethyl acetate, sec-butyl alcohol, sec-amyl alcohol and a combination thereof.

In an embodiment, in the two-step spin coating, the perovskite precursor solution is divided into a first perovskite precursor solution and a second perovskite precursor solution; the first perovskite precursor solution is coated in a previous step of the two-step spin coating, and the second perovskite precursor solution is coated in a subsequent step of the two-step spin coating.

In the previous step of the two-step spin coating, the first perovskite precursor solution is obtained through mixing part of the perovskite raw materials (including PbI₂, or a combination of PbI₂ and MAI), the first solvent and N-(2-ethoxyphenyl)-N′-(2-ethylphenyl) oxamide; and the first perovskite precursor solution is coated on the substrate to obtain a first film after annealing treatment or without annealing treatment;
in the subsequent step of the two-step spin coating, the second perovskite precursor solution is obtained through mixing the other part of the perovskite raw materials and isopropyl alcohol (IPA); and the second perovskite precursor solution is coated on the first film, followed by annealing treatment to obtain the N-(2-ethoxyphenyl)-N′-(2-ethylphenyl) oxamide-doped perovskite film as the perovskite active layer; and
a concentration of Pb²⁺ in the first perovskite precursor solution is 0.01 mol/L-10 mol/L, preferably 0.1 mol/L-4.0 mol/L; and a concentration of N-(2-ethoxyphenyl)-N′-(2-ethylphenyl) oxamide in the first perovskite precursor solution is 0.1 mg/mL-4 mg/mL.

In an embodiment, the spin coating is performed at 15° C.-25° C.

In an embodiment, the annealing treatment is performed at 50° C.-210° C. for 1 min-30 min.

In an embodiment, the annealing treatment is performed in a nitrogen atmosphere, an air atmosphere, or a solvent atmosphere; and the solvent atmosphere comprises a DMSO atmosphere.

In an embodiment, the substrate is made from a material selected from the group consisting of SnO₂, TiO₂, NiOₓ, PTAA, PEDOT:PSS, PC₆₁BM, PC₇₁BM, C₆₀, ICBA, C₇₀, ZnSO₄, CuSCN, CuGaO₂, WOₓ, MoOₓ, Al₂O₃, Nb₂O₅, SiO₂, ZrO₂, Spiro-OMeTAD, P3HT and a combination thereof.

In an embodiment, at least one of the mixing, the coating and the annealing treatment is performed at a relative humidity of 0%-50%.

In an embodiment, a thickness of the perovskite active layer is 450 nm-600 nm.

This application also provides a method for preparing a N-(2-ethoxyphenyl)-N′-(2-ethylphenyl) oxamide-doped perovskite solar cell, comprising:
(S100) pre-processing a conductive substrate layer;
(S200) depositing a lower interfacial transport layer on the conductive substrate layer;
(S300) mixing perovskite raw materials and N-(2-ethoxyphenyl)-N′-(2-ethylphenyl) oxamide in a solvent to obtain a perovskite precursor solution; and coating the perovskite precursor solution on the lower interfacial transport layer, followed by annealing treatment to obtain a perovskite active layer;
(S400) depositing an upper interfacial transport layer on the perovskite active layer; and
(S500) forming a metal electrode on the upper interfacial transport layer to obtain the N-(2-ethoxyphenyl)-N′-(2-ethylphenyl) oxamide-doped perovskite solar cell.

In an embodiment, the metal electrode is formed through vacuum thermal evaporation at a speed 0.1 nm/s-0.15 nm/s.

This application has the following beneficial effects.

A multifunctional oxamide ultraviolet absorber UV312 is doped in the perovskite active layer, which effectively passivates uncoordinated Pb²⁺ in the perovskite active layer, reduces defect density, and hinders the formation of recombination center. Moreover, crystallinity of the perovskite film is regulated, and a grain size is increased, resulting in an improved crystal quality. An energy level structure of the perovskite active layer is effectively regulated, which makes it more compatible with an energy level of the upper interfacial transport layer, thereby accelerating the extraction and transport of the carriers. UV312 can effectively alleviate the residual tensile strain of the perovskite, and further improve mechanical properties and stability of devices. In addition, the multifunctional oxamide ultraviolet absorber can eliminate harmful ultraviolet ray through a photoinduced proton transfer process, which protects the perovskite solar cell from ultraviolet degradation. This application effectively improves the power conversion efficiency and ultraviolet tolerance of the perovskite solar cell.

### BRIEF DESCRIPTION OF THE DRAWINGS

FIG. 1 shows a structure of a perovskite solar cell according to an embodiment of the present disclosure.

FIG. 2a is a scanning electron microscope (SEM) image of an undoped perovskite film according to an embodiment of the present disclosure.

FIG. 2b is a SEM image of a UV312-doped perovskite film according to an embodiment of the present disclosure.

FIG. 3a is a SEM image of an undoped buried perovskite film according to an embodiment of the present disclosure.

FIG. 3b is a SEM image of a buried UV312-doped perovskite film according to an embodiment of the present disclosure.

FIG. 4 shows steady-state fluorescence spectra of the undoped perovskite film (curve a) and the UV312-doped perovskite film (curve b) according to an embodiment of the present disclosure.

FIG. 5 shows an ultraviolet-visible absorption spectrum of UV312.

FIG. 6 shows current density-voltage (J-V) characteristic curves of an undoped flexible perovskite solar cell (curve a) and a UV312-doped flexible perovskite solar cell (curve b) according to an embodiment of the present disclosure.

FIG. 7 shows bending stability test curves of the undoped flexible perovskite solar cell and the UV312-doped flexible perovskite solar cell according to an embodiment of the present disclosure.

FIG. 8 shows an energy level diagram of a material used in a flexible perovskite solar cell according to an embodiment of the present disclosure.

FIG. 9a shows a grazing incidence X-ray diffraction (GIXRD) image of a crystal face of a standard perovskite film (110).

FIG. 9b shows a GIXRD image of a crystal face of the UV312-doped perovskite film (110) according to an embodiment of the present disclosure.

FIG. 9c shows an interplanar spacing value d-spacing obtained from a perovskite (110) plane at different grazing incidence angles according to an embodiment of the present disclosure.

FIG. 10 shows J-V characteristic curves of an undoped rigid perovskite solar cell (curve a) and a UV312-doped rigid perovskite solar cell (curve b) according to an embodiment of the present disclosure.

FIG. 11 shows ultraviolet stability decay curves of the undoped perovskite solar cell and the UV312-doped perovskite solar cell according to an embodiment of the present disclosure.

### DETAILED DESCRIPTION OF EMBODIMENTS

Unless otherwise specified, experimental methods in the following embodiments are performed in accordance with conventional conditions or conditions suggested by manufacturers, and various commonly used chemical reagents used in the embodiments are commercially available.

Unless otherwise defined, technical terms used herein have the same meaning as commonly understood by those of ordinary skill in the art. The technical terms used herein are only illustrative, and are not intended to limit this application.

The terms “including”, “comprising” and any variation thereof, are intended to cover a non-exclusive inclusion. For example, the described process, method, equipment, product and device is not limited to the listed steps or modules, but optionally includes steps or modules which are not listed, or other steps or modules inherent thereto.

The term “multiple” described herein means two or more. The terms “and/or” used herein includes three solutions, for example, “A” and/or “B” includes solution “A”, solution “B”, and a combination thereof. The symbol “/” generally indicates an “or” relationship between associated objects.

The present disclosure provides a N-(2-ethoxyphenyl)-N′-(2-ethylphenyl) oxamide-doped perovskite active layer and a perovskite solar cell including the same. The doping with N-(2-ethoxyphenyl)-N′-(2-ethylphenyl) oxamide effectively improves the crystal quality of perovskite, passivates interior and interface defect states of the perovskite, and reduces a non-radiative recombination of a perovskite solar cell. The present disclosure also regulates an energy level structure of a perovskite active layer, which makes the perovskite active layer more compatible with an energy level of an upper interfacial transport layer and accelerates extraction and transport efficiency of a carrier. In addition, the present disclosure effectively alleviates a residual tensile strain of the perovskite active layer, and improves an anti-ultraviolet capability of the perovskite active layer. Therefore, the present disclosure can improve an ultraviolet light stability and water-oxygen stability of the perovskite solar cell while improving a power conversion efficiency of the perovskite solar cell.

An oxamide ultraviolet absorber described in the present disclosure is N-(2-ethoxyphenyl)-N′-(2-ethylphenyl) oxamide (C₁₈H₂₀N₂O₃; CAS: 23949-66-8; EINECS number: 245-950-9), also referred to as UV312 herein.

A perovskite active layer is provided, including a perovskite film and an oxamide ultraviolet absorber, where the oxamide ultraviolet absorber is doped into the perovskite film, and the oxamide ultraviolet absorber is N-(2-ethoxyphenyl)-N′-(2-ethylphenyl) oxamide, represented by:

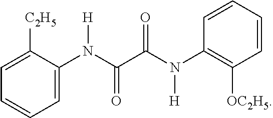 [SMILES: CCOc1ccccc1NC(=O)C(=O)Nc1ccccc1CC]

In an embodiment, the perovskite film has a perovskite structure represented by ABX₃, where A is selected from the group consisting of a cesium ion (Cs⁺), a formamidinium ion (FA⁺), a methylammonium ion (MA⁺) and a combination thereof; B is a lead ion (Pb²⁺); and X is selected from the group consisting of an iodide ion (I⁻), a chloride ion (Cl⁻), a bromide ion (Br⁻) and a combination thereof.

Irons A, B and X of ABX₃ can be chosen to produce various perovskite halides, such as CsₓFA_{y}MA_{1-x-y}PbIₘClₙBr₃₋ₘ₋ₙ, where 0≤x≤1, 0≤y≤1, 0≤m≤3 and 0≤n≤3. Therefore, the perovskite halides may have more than one halogen element, and various halogen elements may exist in non-integer quantities. For example, m may not be equal to 1, 2, or 3. In addition, the perovskite halides, like other organic-inorganic perovskite, can form three-dimensional (3-D), two-dimensional (2-D), one-dimensional (1-D), or zero-dimensional (0-D) networks with the same cellular structure.

In an embodiment, the perovskite halides have a general formula of CsₓFA_{y}MA_{1-x-y}PbIₘClₙBr₃₋ₘ₋ₙ, where 0≤x≤1, 0≤y≤1, 0≤m≤3 and 0n≤3; and x, y, m, n can be non-integer. The general formula of CsₓFA_{y}MA_{1-x-y}PbIₘClₙBr₃₋ₘ₋ₙ is in accordance with the structure of ABX₃. For example, A is selected from a group consisting of a cesium ion (Cs⁺), a formamidinium ion (FA⁺), a methylammonium ion (MA⁺) and a combination thereof; B is a lead ion (Pb²⁺); and X is selected from a group consisting of an iodide ion (I⁻), a chloride ion (Cl⁻), a bromide ion (Br⁻) and a combination thereof. Any combination is possible provided that charges balance.

A method for preparing the perovskite active layer includes the following steps.
(S1) Perovskite raw materials and N-(2-ethoxyphenyl)-N′-(2-ethylphenyl) oxamide are mixed in a solvent to obtain a perovskite precursor solution.
(S2) The perovskite precursor solution is coated on a substrate.
(S3) The substrate is subjected to annealing treatment to obtain a N-(2-ethoxyphenyl)-N′-(2-ethylphenyl) oxamide-doped perovskite film as the perovskite active layer.

In an embodiment, the perovskite raw materials includes:
a first material selected from the group consisting of formamidine iodide (FAI), methylammonium iodide (MAI), cesium iodide (CsI) and a combination thereof;
a second material, being lead iodide (PbI₂); and
a third material selected from the group consisting of methylammonium bromide (MABr), methylammonium chloride (MACI), lead bromide (PbBr₂), dimethylammonium iodide (DMAI), formamidine bromide (FABr), cesium chloride (CsCl), cesium bromide (CsBr) and a combination thereof.

In an embodiment, the solvent is selected from the group consisting of a first solvent and a second solvent. The first solvent is selected from the group consisting of dimethylformamide (DMF), dimethyl sulfoxide (DMSO), N-Methyl-2-pyrrolidone (NMP), gamma-butyrolactone (GBL), acetonitrile (ACN), and a combination thereof. The second solvent is isopropyl alcohol (IPA).

In an embodiment, the perovskite precursor solution is coated on the substrate through spin coating, and the spin coating is performed at a rate of 800 rpm-6000 rpm for 5 s-60 s.

In an embodiment, based on the number of the spin coating, the spin coating is divided into one-step spin coating or two-step spin coating. In the two-step spin coating, the perovskite precursor solution is divided into a first perovskite precursor solution and a second perovskite precursor solution. The first perovskite precursor solution is coated in a previous step of the two-step spin coating, and the second perovskite precursor solution is coated in a subsequent step of the two-step spin coating.

In an embodiment, in the general formula of CsₓFA_{y}MA_{1-x-y}PbIₘClₙBr₃₋ₘ₋ₙ, X is 0, and n is 0, that is, a structural formula of the perovskite is FA_{y}MA_{1-y}PbIₘBr₃₋ₘ.

The perovskite raw materials include PbI₂, FAI, MABr, and MACI. The solvent includes DME, DMSO and IPA.

AFA_{y}MA_{1-y}PbIₘBr₃₋ₘ perovskite active layer is obtained through the two-step spin coating. In the first perovskite precursor solution, a molar concentration of Pb²⁺ is 0.5 mol/L-2 mol/L, and a weight concentration of UV312 is 0.1 mg/mL-3 mg/mL. The first solvent herein is a mixed solution of DMF and DMSO, where a volume ratio of DMF to DMSO is 18-20:1. In the second perovskite precursor solution, a concentration of FAI is 50 mg/mL-80 mg/mL, and a weight ratio of FAI to MABr to MACI is 10:1:1. The second solvent is IPA.

In an embodiment, in the general formula of CsₓFA_{y}MA_{1-x-y}PbIₘClₙBr₃₋ₘ₋ₙ, X is 0, m is 3, and n is 0, that is, a structural formula of the perovskite is FA_{y}MA_{1-y}PbI₃. The perovskite raw materials include PbI₂, FAI, MAI, and MACI. The solvent includes DMF, DMSO and IPA.

A FA_{y}MA_{1-y}PbI₃ perovskite active layer is obtained through the two-step spin coating. In the first perovskite precursor solution, a molar concentration of Pb²⁺ is 0.5 mol/L-2 mol/L, and a weight concentration of UV312 is 0.1 mg/mL-3 mg/mL. The first solvent herein is a mixed solution of DMF and DMSO, where a volume ratio of DMF to DMSO is 8-10:1. In the second perovskite precursor solution, a concentration of FAI is 80 mg/mL-100 mg/mL, and a weight ratio of FAI to MAI to MACI is 90:6.3:9. The second solvent is IPA.

In an embodiment, in the general formula of CsₓFA_{y}MA_{1-x-y}PbIₘClₙBr₃₋ₘ₋ₙ, X is 0, y is 0, m is 3, and n is 0, that is, a structural formula of the perovskite is MAPbI₃.

The perovskite raw materials include PbI₂ and MAI. The solvent includes DMF, DMSO and IPA.

A MAPbI₃ perovskite active layer is obtained through the two-step spin coating. In the first perovskite precursor solution, a molar concentration of Pb²⁺ is 0.5 mol/L-2 mol/L, a weight concentration of MAI is 30 mg/mL-45 mg/mL, and a weight concentration of UV312 is 0.1 mg/mL-3 mg/mL. The first solvent herein is a mixed solution of DMF and DMSO, where a volume ratio of DMF to DMSO is 8-10:1. In the second perovskite precursor solution, a weight concentration of MAI is 30 mg/mL-45 mg/mL. The second solvent is IPA.

In an embodiment, the structural formula of the perovskite is MAPbI₃. The perovskite raw materials include PbI₂ and MAI. The solvent includes DMF and DMSO.

A MAPbI₃ perovskite active layer is obtained through the one-step spin coating with assistance of an anti-solvent, where in the perovskite precursor solution, a molar concentration of Pb²⁺ is 0.5 mol/L-2 mol/L, a weight ratio of MAI to PbI₂ is 1.05:1, and a weight concentration of UV312 is 0.1 mg/mL-3 mg/mL.

The anti-solvent is selected from the group consisting of chlorobenzene, ethanol, isopropanol, methylbenzene, tetrahydrofuran, acetonitrile, ether, ethyl acetate, sec-butyl alcohol, sec-amyl alcohol and a combination thereof.

In an embodiment, in the general formula of CsₓFA_{y}MA_{1-x-y}PbIₘClₙBr₃₋ₘ₋ₙ, X is 0.05, y is 0.9215, m is 2.9145, and n is 0.0855, that is, the structural formula of the perovskite is (CsPbI₃)_{0.05}[(FAPbI₃)_{0.97}(MAPbBr₃)_{0.03}]_{0.95}.

The perovskite raw materials include PbI₂, PbBr₂, FAI, CsI, MABr and MACl.

A (CsPbI₃)_{0.05}[(FAPbI₃)_{0.97}(MAPbBr₃)_{0.03}]_{0.95} perovskite active layer is obtained through the one-step spin coating with assistance of the anti-solvent, where in the perovskite precursor solution, a molar concentration of Pb²⁺ is 0.5 mol/L-2 mol/L, a weight ratio of PbI₂ to PbBr₂ to FAI to CsI to MABr to MACI is 1.46:0.043:1.382:0.075:0.043:0.45, and a weight concentration of UV312 is 0.1 mg/mL-3 mg/mL.

In an embodiment, in the general formula of CsₓFA_{y}MA_{1-x-y}PbIₘClₙBr₃₋ₘ₋ₙ, X is 1, y is 0, m is 3, and n is 0, that is, the structural formula of the perovskite is CsPbI₃. The perovskite raw materials include CsI, DMAI and PbI₂.

In the perovskite precursor solution, a molar concentration of Pb²⁺ is 0.5 mol/L-2 mol/L, a weight ratio of PbI₂ to CsI to DMAI is 1:1:1, and a weight concentration of UV312 is 0.1 mg/mL-3 mg/mL.

In an embodiment, a thickness of the perovskite active layer is 450 nm-600 nm.

The doping of N-(2-ethoxyphenyl)-N′-(2-ethylphenyl) oxamide is a chemical doping. C═O group and C₂H₅O-group in the N-(2-ethoxyphenyl)-N′-(2-ethylphenyl) oxamide can form coordination bonds with the uncoordinated Pb²⁺ in the perovskite, and there is a hydrogen bond interaction between-NH group in the N-(2-ethoxyphenyl)-N′-(2-ethylphenyl) oxamide and I⁻ in the perovskite.

Those of ordinary skill in the art can prepare the N-(2-ethoxyphenyl)-N′-(2-ethylphenyl) oxamide-doped perovskite films (CsₓFA_{y}MA_{1-x-y}PbIₘClₙBr₃₋ₘ₋ₙ) with different structural formulas according to various needs. The perovskite precursor needed herein and its dosage can be calculated according to target chemical formula and dosages of N-(2-ethoxyphenyl)-N′-(2-ethylphenyl) oxamide and lead ion.

The present disclosure also provides a perovskite solar cell. The perovskite solar cell includes a conductive substrate layer, a lower interfacial transport layer, the perovskite active layer, an upper interfacial transport layer and a metal electrode, where the conductive substrate layer, the lower interfacial transport layer, the perovskite active layer, the upper interfacial transport layer and the metal electrode are sequentially arranged from bottom to top. The perovskite active layer is the N-(2-ethoxyphenyl)-N′-(2-ethylphenyl) oxamide-doped perovskite film.

In an embodiment, the conductive substrate layer is a base of the solar cell, which is usually a glass or plastic substrate coated with a transparent conductive material. The conductive substrate layer, as the base of the solar cell, introduces sunlight and collects generated the carrier.

In an embodiment, the conductive substrate layer includes a substrate and a conductive material, and the substrate is made from a material selected from the group consisting of glass, sapphire, polyethylene terephthalate (PET), polyethylene naphthalate (PEN), polyimide (PI), polycarbonate (PC), polyethersulfone (PES), polydimethylsiloxane (PDMS), thermoplastic polyurethane (TPU), metal foil (Ti foil and Cu foil). The conductive material is selected from the group consisting of indium tin oxide (ITO), indium-doped zinc oxide (IZO), aluminum-doped zinc oxide (AZO), fluorine-doped tin oxide (FTO,) a silver nanowire, a composite material composed of the silver nanowire and a two-dimensional material, a carbon-based nanomaterial and a metal mesh.

The lower interfacial transport layer is arranged between the conductive substrate layer and the perovskite active layer (light-absorbing layer). The lower interfacial transport layer is made from a material selected from the group consisting of SnO₂, TiO₂, NiOₓ, poly[bis(4-phenyl) (2,4,6-trimethylphenyl)amine] (PTAA), poly(3,4-ethylenedioxythiophene-poly(styrenesulfonate) (PEDOT:PSS), [6,6] phenyl-C₆₁-butyric acid methyl ester (PC₆₁BM), [6,6] phenyl-C₇₁-butyric acid methyl ester (PC₇₁BM), C₆₀, indene-C₆₀ bis-adduct (ICBA), C₇₀, ZnSO₄, CuSCN, CuGaO₂, WOₓ, MoOₓ, Al₂O₃, Nb₂O₅, SiO₂, ZrO₂, 2,2′,7,7′-Tetrakis[N,N-di(4-methoxyphenyl)amino]-9,9′-spirobifluorene (Spiro-OMeTAD), poly(3-hexylthiophene) (P3HT) and a combination thereof. Based on a specific structure of the perovskite solar cell, the lower interfacial transport layer can be an electron transport layer or a hole transport layer.

The perovskite active layer (light-absorbing layer) is a core of perovskite solar cell.

The perovskite active layer herein is the N-(2-ethoxyphenyl)-N′-(2-ethylphenyl) oxamide-doped perovskite film, which has a general formula of CsₓFA_{y}MA_{1-x-y}PbIₘClₙBr₃₋ₘ₋ₙ, where 0≤x≤1, 0≤y≤1, 0≤m≤3 and 0n≤3. A crystal structure of the N-(2-ethoxyphenyl)-N′-(2-ethylphenyl) oxamide-doped perovskite film is similar to a natural perovskite CaTiO₃, and these materials have excellent power conversion properties, which can effectively convert the energy of sunlight into electricity. A preparation process and properties of the perovskite active layer have a decisive influence on an overall performance of perovskite solar cell.

The upper interfacial transport layer is made from a material selected from the group consisting of SnO₂, TiO₂, NiOₓ, poly[bis(4-phenyl) (2,4,6-trimethylphenyl)amine] (PTAA), poly(3,4-ethylenedioxythiophene-poly(styrenesulfonate) (PEDOT:PSS), [6,6] phenyl-C₆₁-butyric acid methyl ester (PC₆₁BM), [6,6] phenyl-C₇₁-butyric acid methyl ester (PC₇₁BM), C₆₀, indene-C₆₀ bis-adduct (ICBA), C₇₀, ZnSO₄, CuSCN, CuGaO₂, WOₓ, MoOₓ, Al₂O₃, Nb₂O₅, SiO₂, ZrO₂, 2,2′,7,7′-Tetrakis[N,N-di(4-methoxyphenyl)amino]-9,9′-spirobifluorene (Spiro-OMeTAD), poly(3-hexylthiophene) (P3HT) and a combination thereof.

The metal electrode, as a last layer formed on the perovskite solar cell, is configured to collect the carrier and connect with an external circuit. The metal electrode is usually made by steaming a layer of Au, Ag or Cu to improve a conductivity of electrode.

In an embodiment, according to specific designs and functional needs, the perovskite solar cell further includes an upper interface modification layer and a lower interface modification layer, so as to further improve properties and stability of the perovskite solar cell. Cooperation of the components enables the perovskite solar cell to efficiently absorb the sunlight and convert it into the electricity.

The present disclosure will be further described with reference with specific examples.

In the following embodiments, at least one of the mixing, the coating and the annealing treatment is performed at a relative humidity of 0%-50%.

### Example 1

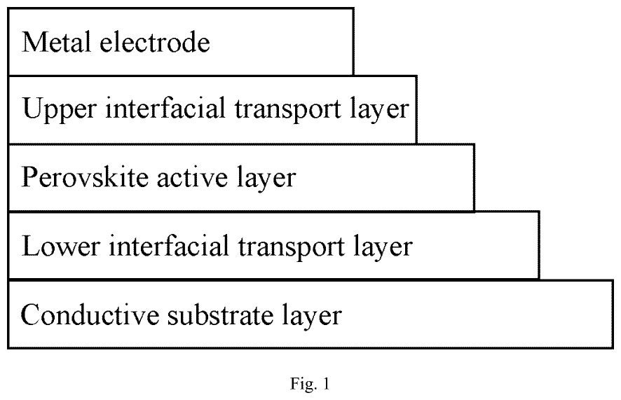

Referring to FIG. 1, the perovskite solar cell included the conductive substrate layer, the lower interfacial transport layer, the perovskite active layer, the upper interfacial transport layer and the metal electrode arranged successively.

The structure of the perovskite solar cell was specifically PEN/ITO/SnO₂/UV312-doped perovskite active layer/Spiro-OMeTAD/Ag, where PEN/ITO represented the conductive substrate layer; SnO₂ represented the lower interfacial transport layer; the UV312-doped perovskite active layer (FA_{y}MA_{1-y}PbIₘBr₃₋ₘ: UV312) represented the perovskite active layer; Spiro-OMeTAD represented the upper interfacial transport layer; and Ag represented the metal electrode.

The perovskite solar cell was prepared through the following steps.

(S100) The conductive substrate layer (PEN/ITO) was pre-processed, where the conductive substrate layer was successively placed in deionized water, acetone, isopropyl alcohol for ultrasonic cleaning, followed by drying, and then was subjected to ultraviolet ozone pretreatment.

(S200) The lower interfacial transport layer SnO₂ was formed on the conductive substrate layer through spin coating, where a SnO₂ colloid water dispersion and deionized water were mixed with a volume of 1:4, followed by even shaking to form a SnO₂ precursor solution; and the SnO₂ precursor solution was coated on the conductive substrate layer (PEN/ITO) through solution spin coating with a coating speed of 4000 rpm for 30 s, followed by heat treatment in the air at 120° C. for 30 min.

(S300) The UV312-doped perovskite active layer was prepared through two steps.

(S311) PbI₂ and UV312 were dissolved in a mixed solvent of DMF and DMSO to form a mixed precursor solution of PbI₂ and UV312, where a concentration of PbI₂ was 1.3 mol/L, a volume ratio of DMF to DMSO was 19:1, and a weight concentration of UV312 was 0.1 mg/mL-3 mg/mL.

(S312) FAI, MABr and MACI with a weight ratio of 10:1:1 were dissolved in IPA to form an organic cation solution, where a concentration of FAI was 60 mg/mL.

(S313) In the nitrogen environment, a temperature of the nitrogen environment was kept at 15° C.-25° C. The mixed precursor solution of PbI₂ and UV312 was coated on the lower interfacial transport layer SnO₂ through spin coating at a coating speed of 1500 rpm-1800 rpm for 30 s-40 s, followed by annealing treatment at 70° C. for 1 min-3 min in the nitrogen environment to form a PbI₂ precursor film.

(S314) In the nitrogen environment, the organic cation solution was coated on the PbI₂ precursor film through spin coating at a coating speed of 1500 rpm-2000 rpm for 30 s-40 s, followed by annealing treatment at 100° C.-130° C. for 20 min-30 min and cooling, and the UV312-doped perovskite active layer was prepared. A thickness of the UV312-doped perovskite active layer was 450 nm-600 nm.

(400) The upper interfacial transport layer was prepared through the following steps. 72.3 mg of Spiro-OMeTAD was dissolved in 1 mL of chlorobenzene, followed by fully stirring and shaking. 18 μL of lithium bis(trifluoromethylsulphonyl)imide (LiTFSI) with a concentration of 520 mg/mL and 29 μL of 4-tert-butylpyridine (TBP) were added, followed by fully stirring and shaking to obtain a mixed solution. The mixed solution was coated on the UV312-doped perovskite active layer through solution spin coating at a coating speed of 4000 rpm for 30 s.

(S500) The metal electrode was made of Ag, and is formed by evaporating, where an evaporating speed was 0.13 nm/s, and a thickness of the metal electrode was 100 nm. A UV312-doped perovskite solar cell was formed.

A preparation method of a perovskite solar cell without doping of UV312 was similar to the UV312-doped perovskite solar cell, except step (300) of the preparation method of the perovskite solar cell without UV312 was as follows.

(S300) A FA_{y}MA_{1-y}PbIₘBr₃₋ₘ perovskite film was prepared through two steps.

(S311) PbI₂ was dissolved in a mixed solvent of DMF and DMSO to form a PbI₂ precursor solution, where a concentration of PbI₂ was 1.3 mol/L, and a volume ratio of DMF to DMSO was 19:1.

(S312) FAI, MABr and MACI with a weight ratio of 10:1:1 were dissolved in IPA to form an organic cation solution, where a concentration of FAI was 60 mg/mL.

(S313) In the nitrogen environment, a temperature of the nitrogen environment was kept at 15° C.-25° C. The PbI₂ precursor solution was coated on the lower interfacial transport layer SnO₂ through spin coating at a coating speed of 1500 rpm-1800 rpm for 30 s-40 s, followed by annealing treatment at 70° C. for 1 min-3 min in the nitrogen environment to form a PbI₂ precursor film. The organic cation solution was coated on the PbI₂ precursor film through spin coating at a coating speed of 1500 rpm-2000 rpm for 30 s-40 s, followed by annealing treatment at 100° C.-130° C. for 20 min-30 min and cooling, and a perovskite active layer without UV312 was obtained. A thickness of the perovskite active layer without UV312 was 450 nm-600 nm.

The UV312-doped perovskite active layer, the UV312-doped perovskite solar cell, the perovskite active layer without UV312 and the perovskite solar cell without UV312 were subjected to performance tests.

Results of the performance tests were described as follows.

An instrument used for scanning electron microscope (SEM) tests was JSM-7100F from Japan Electronics, and was configured to observe surface morphologies and grain sizes of perovskite active layers above. Results of the SEM tests were shown as follows.

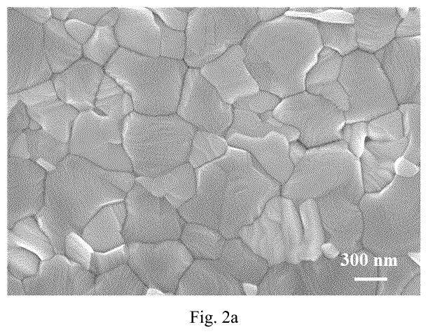

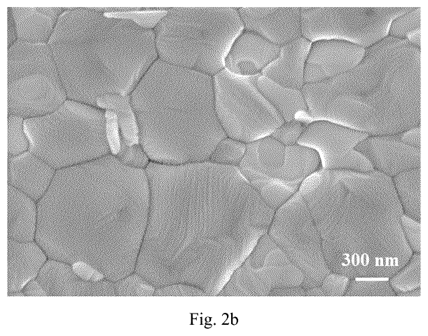

FIG. 2a shows a SEM image of the perovskite active layer without UV312, where an average grain size of the perovskite active layer without UV312 was 464 nm. FIG. 2b shows a SEM image of the UV312-doped perovskite film, where an average grain size of the UV312-doped perovskite film was 722 nm. Compared with the perovskite active layer without UV312, the grain size of the UV312-doped perovskite film increased by 56%.

A preparation method of buried perovskite film was as follows.

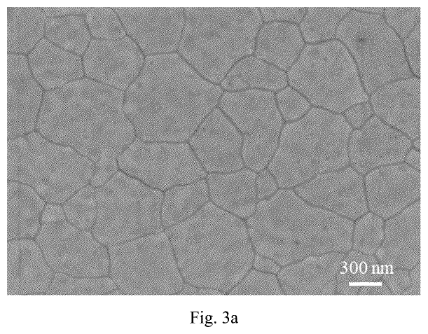

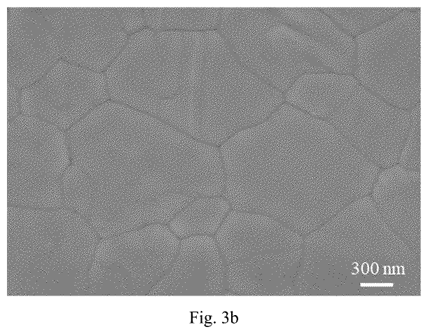

A perovskite film was stripped from a glass substrate to obtain a buried interface, which was described as follows. A surface of the perovskite film was coated with a UV-curable adhesive, and then was covered with a glass. The glass was applied by force, followed by expose by an ultraviolet lamp for 5 minutes to cure the UV-curable adhesive. The glass substrate and the glass were grabbed by two tweezers, and then the perovskite film was stripped from the substrate. The buried perovskite film was subjected to SEM tests, and results were showed in FIGS. 3a-3b.

FIG. 3a shows a SEM image of an undoped buried perovskite film, where an average grain size of the undoped buried perovskite film was 491 nm. FIG. 3b shows a SEM image of a UV312-doped buried perovskite film, where an average grain size of the UV312-doped buried perovskite film was 791 nm. Compared with the undoped buried perovskite film, the grain size of the UV312-doped buried perovskite film increased while a grain boundary decreased.

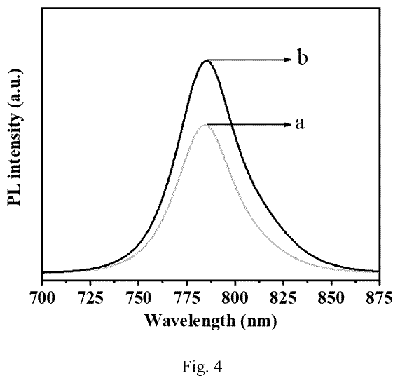

Fluorescence spectrums were tested through Edinburgh FLS980, which was configured to test a fluorescence intensity of the perovskite film, and test results were showed in FIG. 4.

In FIG. 4, a shows a steady-state fluorescence spectra of the undoped perovskite film, and b shows a steady-state fluorescence spectra of the UV312-doped perovskite film. Compared with the perovskite film without doping, the steady-state fluorescence spectra of the UV312-doped perovskite film increased. A difference between the peaks of a and b is 42%.

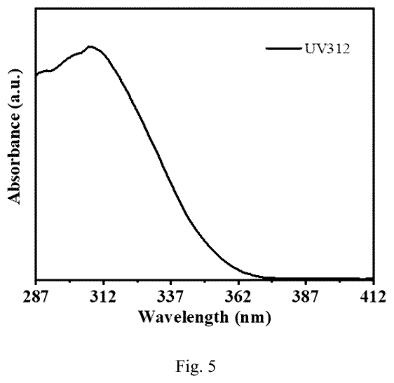

An ultraviolet-visible (UV-vis) absorption spectrum was tested by UV-2600 (Shimadzu), which was configured to test an absorption range of UV312. A result was shown in FIG. 5.

FIG. 5 shows an ultraviolet-visible absorption spectrum of UV312. UV312 can effectively absorb ultraviolet light below 387 nm.

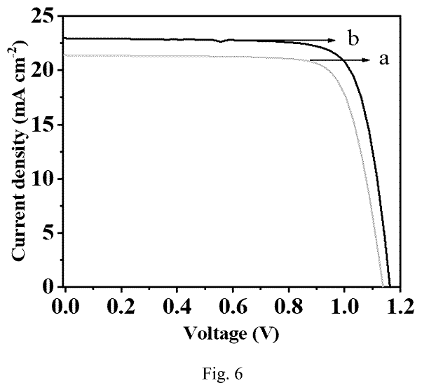

A current density-voltage (J-V) characteristic curves was tested through a solar simulator (ABET SUN3000) connected with a digital source table (keithley 2400) under 100 mW/cm² simulated sunlight conditions. A light source intensity was calibrated, by a standard silicon solar cell (ABET technology), to AM 1.5, 100 mW/cm², which was configured to accurately calculate performance parameters of the perovskite solar cell, and results were shown in FIG. 6.

FIG. 6 shows current density-voltage (J-V) characteristic curves of an undoped flexible perovskite solar cell (curve a) and a UV312-doped flexible perovskite solar cell (curve b). Referring to FIG. 6, the undoped flexible perovskite solar cell had an open-circuit voltage of 1.14 V, a short circuit current density of 21.41 mA/cm², a fill factor of 77%, and a power conversion efficiency of 18.88%. The UV312-doped flexible perovskite solar cell had an open-circuit voltage of 1.16 V, a short circuit current density of 22.96 mA/cm², a fill factor of 78%, and a power conversion efficiency of 20.87%. Compared with the undoped flexible perovskite solar cell, the UV312-doped flexible perovskite solar cell increased.

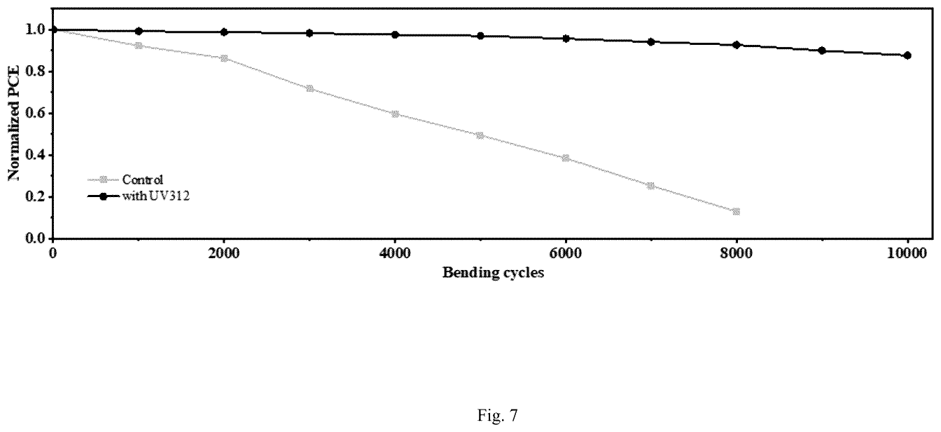

FIG. 7 shows bending stability decay curves of the undoped flexible perovskite solar cell and the UV312-doped flexible perovskite solar cell. Under a condition of bending radius of 5 mm, the UV312-doped flexible perovskite solar cell maintained about 88% of its initial power conversion efficiency (PCE), the flexible perovskite solar cell without doping maintained about 13% of its initial PCE. Compared with the undoped flexible perovskite solar cell, the bending stability of the UV312-doped flexible perovskite solar cell increased.

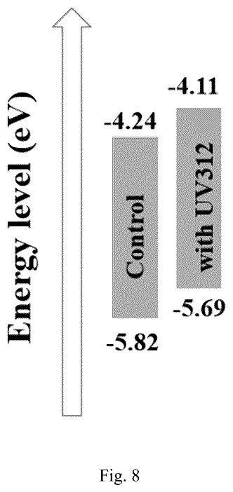

Ultraviolet photoelectron spectroscopy (UPS) was tested through Thermo Fisher Scientific ESCALAB Xi+, which was configured to characterize an energy level change of the perovskite film. Results were shown in FIG. 8.

FIG. 8 shows an energy level image of a corresponding material used in a device. A valence band of UV312-doped perovskite increased from −5.82 eV to −5.69 eV, which was closer to a highest occupied molecular orbital (HOMO) energy level of Spiro-OMeTAD (−5.2 eV). Therefore, an energy barrier between the perovskite and Spiro-OMeTAD was reduced, and energy levels were matched, which facilitated to efficiently extract interface charges.

Grazing incidence X-ray diffraction (GIXRD) image was tested through Bruker D8 Advance, which was configured to characterize a tensile strain change of the perovskite film.

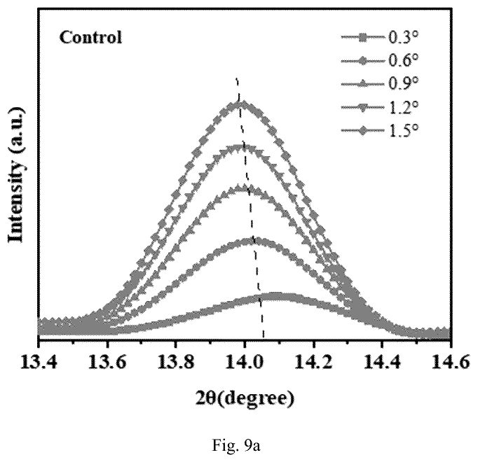

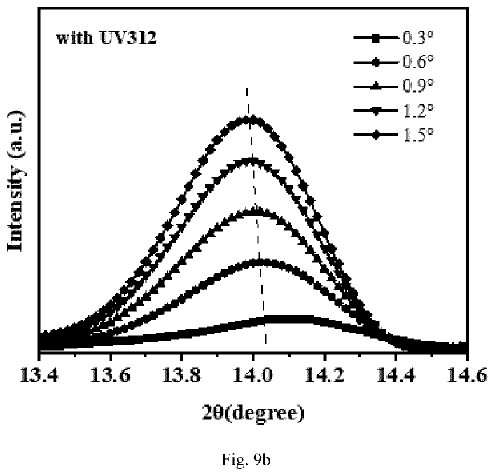

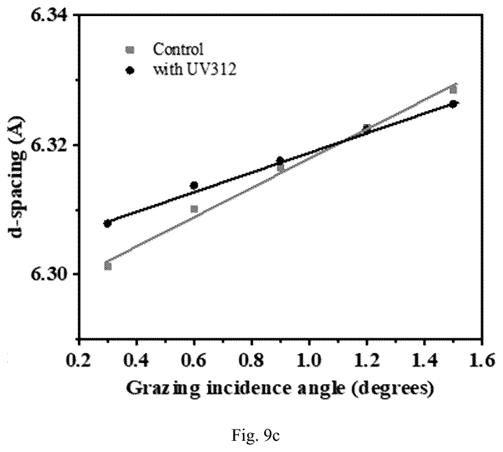

FIG. 9a shows a GIXRD image of a standard perovskite film (110) plane. FIG. 9b shows a GIXRD image of the UV312-doped perovskite film (110) plane. FIG. 9c shows an interplanar spacing value d-spacing obtained from a perovskite (110) plane at different grazing incidence angles. For the standard perovskite film, a grazing incidence angle (ω) changed from 0.3° to 1.5°, and a characteristic diffraction peak (110) of the perovskite moved to a peak of a low diffraction angle, indicating that there is lattice expansion caused by a tensile strain in the standard perovskite film. With the increase of w value, a diffraction peak displacement of the UV312-doped perovskite film was smaller, indicating that a tensile strain of the UV312-doped perovskite film was significantly reduced. Besides, an interplanar spacing value d-spacing of the (110) plane was calculated through Bragg equation. For the standard perovskite film, when the grazing incidence angle changed from 0.3° to 1.5°, the d-spacing of the (110) plane changed significantly, while d-spacing of the (110) plane of the UV312-doped perovskite film changed little. The diffraction peak shifted to a lower angle indicated that an increase of the interplanar spacing value, which led to lattice expansion and eventually to stress and strain. After the doping of the UV312, the residual tensile strain in the perovskite film was significantly released.

### Example 2

This example prepared a UV312-doped perovskite solar cell.

A preparation method of this example was the same as that of Example 1, except that in step (S100), the conductive substrate layer was glass/ITO.

Test results were shown as follows.

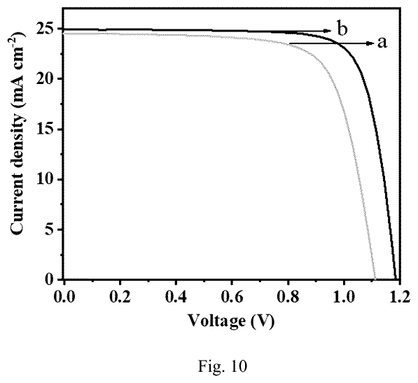

FIG. 10 shows J-V curves of an undoped perovskite solar cell (curve a) and a UV312-doped perovskite solar cell (curve b). A power conversion efficiency of the undoped perovskite solar cell was 19.89%, and a power conversion efficiency of the UV312-doped perovskite solar cell was 23.09%. Compared with the undoped perovskite solar cell, the power conversion efficiency of the UV312-doped perovskite solar cell increased.

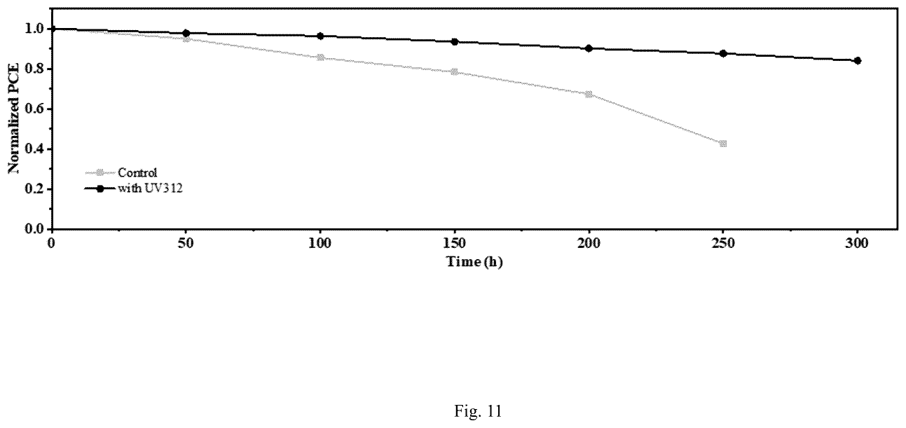

FIG. 11 shows ultraviolet stability decay curves of the perovskite solar cell without doping and the UV312-doped perovskite solar cell. The perovskite solar cell without doping maintained 43% of its initial power conversion efficiency after 250 h of UV irradiation. The UV312-doped perovskite solar cell maintained 84% of its initial power conversion efficiency after 300 h of UV irradiation. Compared with the undoped perovskite solar cell, the stability of the UV312-doped perovskite solar cell increased.

### Example 3

This example prepared a UV312-doped perovskite solar cell.

A preparation method of this example was the same as that of Example 1, except that in step (S300), the perovskite active layer was a UV312-doped FA_{y}MA_{1-y}PbI₃ perovskite film. The UV312-doped FA_{y}MA_{1-y}PbI₃ perovskite film was prepared through two-step spin coating as follows.

(S321) PbI₂ and UV312 were dissolved in a mixed solvent of DMF and DMSO to form a mixed precursor solution of PbI₂ and UV312, where a volume ratio of DMF to DMSO was 19:1, a concentration of PbI₂ was 1.5 mol/L, and a weight concentration of UV312 was 0.25 mg/mL.

(S322) FAI, MAI and MACI with a weight ratio of 90:6.3:9 were dissolved in IPA to form an organic cation solution, where a concentration of FAI was 90 mg/mL.

(S323) In the nitrogen environment, a temperature of the nitrogen environment was kept at 15° C.-25° C. The mixed precursor solution of PbI₂ and UV312 was coated on the lower interfacial transport layer through spin coating at a coating speed of 1300 rpm-2000 rpm for 30 s-40 s, followed by annealing treatment at 70° C. for 1 min-3 min in the nitrogen environment to form a PbI₂ precursor film.

(S324) In the nitrogen environment, the temperature of the nitrogen environment was kept at 15° C.-25° C. The organic cation solution was coated on the PbI₂ precursor film through spin coating at a coating speed of 1300 rpm-2000 rpm for 30 s-40 s, followed by annealing treatment at 100° C.-150° C. for 15 min-30 min and cooling, and the UV312-doped perovskite film was obtained.

### Example 4

This example prepared a UV312-doped perovskite solar cell.

A preparation method of this example was the same as that of Example 1, except that in step (S300), the perovskite active layer was a UV312-doped MAPbI₃ perovskite film. The UV312-doped MAPbI₃ perovskite film was prepared through following steps.

(S331) DMF and DMSO were mixed to form a mixed solvent, and a volume ratio of DMF to DMSO 9:1. PbI₂ and MAI were dissolved in the mixed solvent to form a mixed precursor solution of PbI₂ and MAI, where a concentration of PbI₂ was 599.3 mg/mL, and a concentration of MAI was 40 mg/mL. UV312 was dissolved in the mixed precursor solution of PbI₂ and MAI, and a weight concentration of the UV312 was 0.25 mg/mL.

(S322) MAI was dissolved in isopropanol to obtain a 30 mg/mL MAI solution.

(S333) In the nitrogen environment, a temperature of the nitrogen environment was kept at 15° C.-25° C. The precursor solution of PbI₂ and MAI was coated on the lower interfacial transport layer through spin coating at a coating speed of 4000 rpm for 10 s to form a first film.

(S334) The 30 mg/mL MAI solution was coated on the first film at a coating speed of 4000 rpm for 30 s, followed by annealing treatment at 100° C. for 15 min in the air to obtain the UV312-doped MAPbI₃ perovskite film.

### Example 5

This example prepared a UV312-doped perovskite solar cell.

A preparation method of this example was the same as that of Example 1, except that in step (S300), the perovskite active layer was a UV312-doped MAPbI₃ perovskite film. The UV312-doped MAPbI₃ perovskite film was prepared through following steps.

(S341) DMF and DMSO were mixed to form a mixed solvent, and a volume ratio of DMF to DMSO 9:1. PbI₂ and MAI were dissolved in the mixed solvent to form a mixed precursor solution of PbI₂ and MAI, where a molar ratio of MAI to PbI₂ was 1.05:1, a molar concentration of the MAI was 2.1 mol/L, and a molar concentration of the PbI₂ was 2 mol/L, so as to form a MAPbI₃ perovskite precursor solution. UV312 was dissolved in the MAPbI₃ perovskite precursor solution, where a weight concentration of the UV312 was 0.25 mg/mL.

(S342) In the nitrogen environment, a temperature of the nitrogen environment was kept at 15° C.-25° C. The MAPbI₃ perovskite precursor solution was coated on the lower interfacial transport layer through spin coating at a coating speed of 5000 rpm for 30 s, where at 5 s-15 s before the end of spin coating, an anti-solvent selected from the group consisting of chlorobenzene, ethanol, isopropanol, methylbenzene, tetrahydrofuran, acetonitrile, ether, ethyl acetate, sec-butyl alcohol, sec-amyl alcohol and a combination thereof was added for cleaning, and an addition amount of the anti-solvent was 100 μL. The film was subjected to annealing treatment at 100° C. for 15 min in the air, and then was subjected to solvent auxiliary annealing treatment in an atmosphere of DMSO for 5 min, followed by cooling to obtain the UV312-doped MAPbI₃ perovskite film.

### Example 6

This example prepared a UV312-doped perovskite solar cell.

A preparation method of this example was the same as that of Example 1, except that in step (S300), the perovskite active layer was a (CsPbI₃)_{0.05}[(FAPbI₃)_{0.97}(MAPbBr₃)_{0.03}]_{0.95} perovskite film. The (CsPbI₃)_{0.05}[(FAPbI₃)_{0.97}(MAPbBr₃)_{0.03}]_{0.95} perovskite film was prepared through following steps.

(S351) 671.81 mg of PbI₂, 15.69 mg of PbBr₂, 237.71 mg of FAI, 19.49 mg of CsI, 4.79 mg of MABr and 30.38 mg of MACI were dissolved in a 1 mL of mixed solution of DMF and DMSO to obtain a (CsPbI₃)_{0.05}[(FAPbI₃)_{0.97}(MAPbBr₃)_{0.03}]_{0.95} mixed precursor solution, where a volume ration of DMF to DMSO in the mixed solution of DMF and DMSO was 4:1. UV312 was dissolved in the (CsPbI₃)_{0.05}[(FAPbI₃)_{0.97}(MAPbBr₃)_{0.03}]_{0.95} mixed precursor solution through stirring to obtain a perovskite precursor solution, and a weight concentration of UV312 was 0.25 mg/mL.

(S352) In the nitrogen environment, a temperature of the nitrogen environment was kept at 15° C.-25° C. 80 μL of the perovskite precursor solution was coated on the lower interfacial transport layer through spin coating at a coating speed of 1000 rpm for 10 s, and then at a coating speed of 4000 rpm for 45 s, where at 8 s before the end of spin coating, an anti-solvent selected from the group consisting of chlorobenzene, ethanol, isopropanol, methylbenzene, tetrahydrofuran, acetonitrile, ether, ethyl acetate, sec-butyl alcohol, sec-amyl alcohol and a combination thereof was added at a center of a perovskite precursor film, and then the perovskite precursor film was subjected to annealing treatment at 130° C. for 15 min in the air, followed by cooling to obtain the (CsPbI₃)_{0.05}[(FAPbI₃)_{0.97}(MAPbBr₃)_{0.03}]_{0.95} perovskite film.

### Example 7

This example prepared a UV312-doped perovskite solar cell.

A preparation method of this example was the same as that of Example 1, except that in step (S300), the perovskite active layer was a CsPbI₃ perovskite film. The CsPbI₃ perovskite film was prepared through following steps.

(S361) 182 mg of CsI, 121.1 mg of DMAI and 322.7 mg of PbI₂ were dissolved in a mixed solution of DMF and DMSO through 6 h stirring in the nitrogen environment to obtain a CsPbI₃ precursor solution, where a molar concentration of the CsPbI₃ precursor solution was 0.7 mol/L. UV312 was dissolved in the CsPbI₃ precursor solution through stirring, to obtain a perovskite precursor solution, and a weight concentration of UV312 was 0.25 mg/mL.

(S362) In the nitrogen environment, a temperature of the nitrogen environment was kept at 15° C.-25° C. The perovskite precursor solution was coated through spin coating at a coating speed of 2000 rpm for 30 s, followed by pre-annealing treatment at 70° C. for 1-5 min and annealing treatment at 150-210° C. for 10-20 min.

### Example 8

This example prepared a UV312-doped perovskite solar cell.

A preparation method of this example was the same as that of Example 1, except that in step (S200), the lower interfacial transport layer was TiO₂, the lower interfacial transport layer TiO₂ was prepared through following steps.

A 0.2 mol/L of ethanol solution of titanium diisopropoxide bis(acetylacetonate) was prepared, and then was coated on the conductive substrate layer at a coating speed of 3000 rpm for 30 s, followed by pre-annealing treatment at 125° C. for 5 min and annealing treatment in a muffle furnace at 500° C. for 30 min.

### Example 9

This example prepared a UV312-doped perovskite solar cell.

A preparation method of this example was the same as that of Example 1, except that in step (S400), the upper interfacial transport layer was PTAA, the upper interfacial transport layer PTAA was prepared through following steps.

PTAA was dissolved in chlorobenzene to form a mixed solution, and a weight concentration of PTAA in the mixed solution was 5 mg/mL. The mixed solution was coated on the perovskite active layer through spin coating at a coating speed of 3000 rpm for 30-50 s, followed by annealing treatment at 120° C. for 5-10 min.

### Example 10

This example prepared a UV312-doped perovskite solar cell.

A preparation method of this example was the same as that of Example 1, except that in step (S400), the upper interfacial transport layer was P3HT, the upper interfacial transport layer P3HT was prepared through following steps.

P3HT was dissolved in chlorobenzene to form a mixed solution, and a weight concentration of P3HT in the mixed solution was 10 mg/mL. The mixed solution was coated on the perovskite active layer through spin coating at a coating speed of 3000 rpm for 30-50 s, followed by annealing treatment at 120° C. for 5-10 min.

### Example 11

This example prepared a UV312-doped perovskite solar cell.

A preparation method of this example was the same as that of Example 1, except that in step (S200) and step (S400), the lower interfacial transport layer was PEDOT:PSS and the upper interfacial transport layer was C₆₀, the lower interfacial transport layer PEDOT:PSS and the upper interfacial transport layer C₆₀ were prepared through following steps.

In step (S200), in the air environment, a temperature of the air environment was kept at 15° C.-25° C. A PEDOT:PSS mixed solution was coated on the conductive substrate layer at a coating speed of 3800 rpm for 35 s, and then was subjected to annealing treatment at 130° C. for 15-30 min. In step (S400), the upper interfacial transport layer was C₆₀, and the upper interfacial transport layer C₆₀ was prepared by a vacuum deposition method.

### Example 12

This example prepared a UV312-doped perovskite solar cell.

A preparation method of this example was the same as that of Example 1, except that in step (S200) and step (S400), the lower interfacial transport layer was NiOₓ and the upper interfacial transport layer was PC₆₁BM, the lower interfacial transport layer NiOₓ and the upper interfacial transport layer PC₆₁BM were prepared through following steps.

In step (S200), NiOₓ was dissolved in deionized water to form a NiOₓ mixed solution, and a weight concentration of NiOₓ in the NiOₓ mixed solution was 20 mg/mL. The NiOₓ mixed solution was coated on the conductive substrate layer at a coating speed of 3000-6000 rpm for 30-40 s, followed by annealing treatment at 120° C. for 10-15 min. In step (S400), the upper interfacial transport layer was PC₆₁BM. PC₆₁BM was dissolved in chlorobenzene to form a PC₆₁BM mixed solution, and a weight concentration of PC₆₁BM in the PC₆₁BM mixed solution was 20 mg/mL. The PC₆₁BM mixed solution was coated on the perovskite active layer through spin coating at a coating speed of 2000-5000 rpm for 30-40 s.

### Comparative Example 1

In the preparation method of a UV312-doped perovskite solar cell, a doping concentration of UV312 was adjusted to 10 mg/mL, and the conductive substrate layer was glass/ITO.

The structure of the perovskite solar cell was specifically glass/ITO/SnO₂/FA_{y}MA_{1-y}PbIₘBr₃₋ₘ:UV312/Spiro-OMeTAD/Ag.

The UV312-doped perovskite solar cell was prepared through the following steps.

(S100) The conductive substrate layer was subjected to pre-treatment, where the conductive substrate layer was successively placed in deionized water, acetone, isopropyl alcohol for ultrasonic cleaning, followed by drying, and then was subjected to ultraviolet ozone pretreatment.

(S200) The lower interfacial transport layer SnO₂ was formed on the conductive substrate layer through spin coating, where a SnO₂ colloid water dispersion and deionized water were mixed with a volume of 1:4, followed by even shaking to form a SnO₂ precursor solution; and the SnO₂ precursor solution was coated on the conductive substrate layer through solution spin coating with a coating speed of 4000 rpm for 30 s, followed by heat treatment in the air at 150° C. for 30 min.

(S300) A UV312-doped FA_{y}MA_{1-y}PbIₘBr₃₋ₘ film was prepared through two steps.

(S311) PbI₂ and UV312 were dissolved in a mixed solvent of DMF and DMSO to form a mixed precursor solution of PbI₂ and UV312, where a volume ratio of DMF to DMSO was 19:1, a concentration of PbI₂ was 1.3 mol/L, and a weight concentration of UV312 was 10 mg/mL.

(S312) FAI, MABr and MACI with a weight ratio of 10:1:1 were dissolved in IPA to form an organic cation solution, where a concentration of FAI was 50 mg/mL-80 mg/mL.

(S313) In the nitrogen environment, a temperature of the nitrogen environment was kept at 15° C.-25° C. The mixed precursor solution of PbI₂ and UV312 was coated on the lower interfacial transport layer through spin coating at a coating speed of 1500 rpm-2000 rpm for 30 s-40 s, followed by annealing treatment at 70° C. for 1 min-3 min in the nitrogen environment to form a PbI₂ precursor film. In the nitrogen environment, the organic cation solution was coated on the PbI₂ precursor film through spin coating at a coating speed of 1500 rpm-2000 rpm for 30 s-40 s, followed by annealing treatment at 100° C.-150° C. for 15 min-30 min and cooling, and the UV312-doped FA_{y}MA_{1-y}PbIₘBr₃₋ₘ film was obtained. A thickness of the UV312-doped FA_{y}MA_{1-y}PbIₘBr₃₋ₘ film was 450 nm-600 nm.

(400) The upper interfacial transport layer Spiro-OMeTAD was prepared through the following steps. 72.3 mg of Spiro-OMeTAD was dissolved in 1 mL of chlorobenzene, followed by fully stirring and shaking. 18 μL of lithium bis(trifluoromethylsulphonyl)imide (LiTFSI) with a concentration of 520 mg/mL and 29 μL of 4-tert-butylpyridine (TBP) were added, followed by fully stirring and shaking to obtain a mixed solution. The mixed solution was coated on the UV312-doped FA_{y}MA_{1-y}PbIₘBr₃-m film through solution spin coating at a coating speed of 4000 rpm for 30 s.

(S500) The metal electrode was made of Ag, and is formed by evaporating, where an evaporating speed was 0.13 nm/s, and a thickness of the metal electrode was 100 nm. The UV312-doped perovskite solar cell was obtained.

After testing, an optimal power conversion efficiency of this UV312-doped perovskite solar cell was only 18.07%.

### Comparative Example 2

In the preparation method of a UV312-doped perovskite solar cell, UV312 was doped in a FAI solution, and a concentration of UV312 was 5 mg/mL, and the conductive substrate layer was glass/ITO.

The structure of the perovskite solar cell was specifically glass/ITO/SnO₂/FA_{y}MA_{1-y}PbIₘBr₃₋ₘ:UV312/Spiro-OMeTAD/Ag.

The UV312-doped perovskite solar cell was prepared through the following steps.

(S100) The conductive substrate layer was subjected to pre-treatment, where the conductive substrate layer was successively placed in deionized water, acetone, isopropyl alcohol for ultrasonic cleaning, followed by drying, and then was subjected to ultraviolet ozone pretreatment.

(S200) The lower interfacial transport layer SnO₂ was formed on the conductive substrate layer through spin coating, where a SnO₂ colloid water dispersion and deionized water were mixed with a volume of 1:4, followed by even shaking to form a SnO₂ precursor solution; and the SnO₂ precursor solution was coated on the conductive substrate layer through solution spin coating with a coating speed of 4000 rpm for 30 s, followed by heat treatment in the air at 150° C. for 30 min.

(S300) A UV312-doped FA_{y}MA_{1-y}PbIₘBr₃₋ₘ film was prepared through two steps.

(S311) PbI₂ was dissolved in a mixed solvent of DMF and DMSO to form a mixed precursor solution of PbI₂, where a volume ratio of DMF to DMSO was 19:1, and a concentration of PbI₂ was 1.3 mol/L.

(S312) FAI, MABr and MACI with a weight ratio of 10:1:1 were dissolved in IPA to form an organic cation solution, where a concentration of FAI was 50 mg/mL-80 mg/mL. UV312 was added to the organic cation solution, and a weight concentration of UV312 was 5 mg/mL.

(S313) In the nitrogen environment, a temperature of the nitrogen environment was kept at 15° C.-25° C. The mixed precursor solution of PbI₂ was coated on the lower interfacial transport layer through spin coating at a coating speed of 1500 rpm-2000 rpm for 30 s-40 s, followed by annealing treatment at 70° C. for 1 min-3 min in the nitrogen environment to form a PbI₂ precursor film. In the nitrogen environment, the organic cation solution was coated on the PbI₂ precursor film through spin coating at a coating speed of 1500 rpm-2000 rpm for 30 s-40 s, followed by annealing treatment at 100° C.-150° C. for 15 min-30 min and cooling, and the UV312-doped FA_{y}MA_{1-y}PbIₘBr₃₋ₘ film was obtained. A thickness of the UV312-doped FA_{y}MA_{1-y}PbIₘBr₃₋ₘ film was 450 nm-600 nm.

(400) The upper interfacial transport layer Spiro-OMeTAD was prepared through the following steps. 72.3 mg of Spiro-OMeTAD was dissolved in 1 mL of chlorobenzene, followed by fully stirring and shaking. 18 μL of lithium bis(trifluoromethylsulphonyl)imide (LiTFSI) with a concentration of 520 mg/mL and 29 μL of 4-tert-butylpyridine (TBP) were added, followed by fully stirring and shaking to obtain a mixed solution. The mixed solution was coated on the UV312-doped FA_{y}MA_{1-y}PbIₘBr₃₋ₘ film through solution spin coating at a coating speed of 4000 rpm for 30 s.

(S500) The metal electrode was made of Ag, and is formed by evaporating, where an evaporating speed was 0.13 nm/s, and a thickness of the metal electrode was 100 nm. The UV312-doped perovskite solar cell was obtained.

After testing, an optimal power conversion efficiency of this UV312-doped perovskite solar cell was only 17.41%.

In the present disclosure, the oxamide ultraviolet absorber UV312 is doped in the perovskite active layer, which effectively passivates the uncoordinated Pb²⁺ in the perovskite active layer, reduces the defect density, reduces formation of composite center, regulates crystallinity of the perovskite film, increases a grain size and improves crystal quality. An energy level structure of the perovskite active layer is effectively regulated, which makes it more compatible with an energy level of the upper interfacial transport layer and accelerates the extraction and transport of the carrier. The oxamide ultraviolet absorber can effectively alleviate the residual tensile strain and improve mechanical properties and stability of device. In addition, the multifunctional oxamide ultraviolet absorber eliminates harmful ultraviolet ray through photoinduced proton transfer process, which protects the perovskite solar cell from ultraviolet degradation. The present disclosure effectively improves the power conversion efficiency and ultraviolet tolerance of the perovskite solar cell.

Other ultraviolet absorbers, such as non-oxamide ultraviolet absorbers, have functional groups that do not achieve similar defect passivation. Li J, Qi W, Li Y, et al. (UV light absorbers executing synergistic effects of passivating defects and improving photostability for efficient perovskite photovoltaics[J]. Journal of Energy Chemistry, 2022, 67:138-146) discloses that 2-(2-hydroxy-5-methylphenyl)benzotriazole (UVP), as an ultraviolet absorption passivator, has poorer regulation effect of crystal quality than that of UV312, and fails to show the effect of stress release, and application in flexible perovskite solar cells.

Liu F, Valencia A, Zhu Y, et al. (Melatonin treatment as an anti-aging therapy for UV-related degradation of perovskite solar cells[J]. Journal of Materials Chemistry A, 2024, 12 (20): 11986-11994) discloses that N-acetyl-5-methoxy-tryptamine (melatonin), as an ultraviolet absorption passivator, is used to prepare a rigid perovskite solar cell, and PCE of the rigid perovskite solar cell is 21.11%. However, the perovskite solar cell prepared based on UV312 of the present disclosure has PCE of 23.09%, that is, melatonin cannot achieve the effect similar to UV312. In addition, melatonin also fails to show the effect of stress release, and application in flexible perovskite solar cells.

Xiao G B, Meng R, Yang S, et al. (Cerium oxide nanoparticle as interfacial modifier for efficient and UV-stable perovskite solar cells[J]. Chemical Engineering Journal, 2023, 462:142047) discloses that cerium oxide, as an ultraviolet absorption passivator, fails to show the effect of stress release, and application in flexible perovskite solar cells. The UV312-doped perovskite solar cell of the present disclosure can realize the stress regulation effect on perovskite.

Described above are only some embodiments of this application. It should be noted that for those of ordinary skill in the art, various improvements made without departing the spirit of the present disclosure shall fall within the scope of this application defined by the appended claims.

What is claimed is:

1. A perovskite active layer, comprising:
a perovskite film; and
an oxamide ultraviolet absorber;
wherein the oxamide ultraviolet absorber is doped into the perovskite film; and the oxamide ultraviolet absorber is N-(2-ethoxyphenyl)-N′-(2-ethylphenyl) oxamide.

2. The perovskite active layer of claim 1, wherein the perovskite film has a perovskite structure represented by ABX₃, wherein A is selected from the group consisting of a cesium ion (Cs⁺), a formamidinium ion (FA⁺), a methylammonium ion (MA⁺) and a combination thereof; B is a lead ion (Pb²⁺); and X is selected from the group consisting of an iodide ion (I⁻), a chloride ion (Cl⁻), a bromide ion (Br⁻) and a combination thereof.

3. A perovskite solar cell, comprising:
the perovskite active layer of claim 1.

4. The perovskite solar cell of claim 3, wherein a thickness of the perovskite active layer is 450-600 nm.

5. The perovskite solar cell of claim 3, further comprising:
a conductive substrate layer;
a lower interfacial transport layer;
an upper interfacial transport layer; and
a metal electrode;
wherein the conductive substrate layer, the lower interfacial transport layer, the perovskite active layer, the upper interfacial transport layer and the metal electrode are sequentially arranged from bottom to top.

6. The perovskite solar cell of claim 5, wherein the conductive substrate layer comprises a substrate and a conductive material coated thereon; the substrate is made from a material selected from the group consisting of glass, sapphire, polyethylene terephthalate (PET), polyethylene naphthalate (PEN), polyimide (PI), polycarbonate (PC), polyethersulfone (PES), polydimethylsiloxane (PDMS), thermoplastic polyurethane (TPU), and metal foil; and
the conductive material is selected from the group consisting of indium tin oxide (ITO), indium-doped zinc oxide (IZO), aluminum-doped zinc oxide (AZO), fluorine-doped tin oxide (FTO,) a silver nanowire, a composite material composed of the silver nanowire and a two-dimensional material, a carbon-based nanomaterial and a metal mesh.

7. The perovskite solar cell of claim 5, wherein the lower interfacial transport layer and the upper interfacial transport layer are each independently made from a material selected from the group consisting of SnO₂, TiO₂, NiOₓ, poly[bis(4-phenyl) (2,4,6-trimethylphenyl)amine] (PTAA), poly(3,4-ethylenedioxythiophene-poly(styrenesulfonate) (PEDOT:PSS), [6,6] phenyl-C₆₁-butyric acid methyl ester (PC₆₁BM), [6,6] phenyl-C₇₁-butyric acid methyl ester (PC₇₁BM), C₆₀, indene-C₆₀ bis-adduct (ICBA), C₇₀, ZnSO₄, CuSCN, CuGaO₂, WOₓ, MoOₓ, Al₂O₃, Nb₂O₅, SiO₂, ZrO₂, 2,2′,7,7′-Tetrakis[N,N-di(4-methoxyphenyl)amino]-9,9′-spirobifluorene (Spiro-OMeTAD), poly(3-hexylthiophene) (P3HT) and a combination thereof.

8. The perovskite solar cell of claim 5, wherein the metal electrode is made from a material selected from the group consisting of Au, Ag and Cu.

9. A method for preparing a perovskite active layer, comprising:
(S1) mixing perovskite raw materials and N-(2-ethoxyphenyl)-N′-(2-ethylphenyl) oxamide in a solvent to obtain a perovskite precursor solution;
(S2) coating the perovskite precursor solution on a substrate; and
(S3) subjecting the substrate to annealing treatment to obtain a N-(2-ethoxyphenyl)-N′-(2-ethylphenyl) oxamide-doped perovskite film as the perovskite active layer.

10. The method of claim 9, wherein the perovskite raw materials comprise:
a first material selected from the group consisting of formamidine iodide (FAI), methylammonium iodide (MAI), cesium iodide (CsI) and a combination thereof;
a second material, wherein the second material is lead iodide (PbI₂); and
a third material selected from the group consisting of methylammonium bromide (MABr), methylammonium chloride (MACl), lead bromide (PbBr₂),
dimethylammonium iodide (DMAI), formamidine chloride (FACl), formamidine bromide (FABr), cesium chloride (CsCl), cesium bromide (CsBr) and a combination thereof.

11. The method of claim 10, wherein a ratio of Pb²⁺ to N-(2-ethoxyphenyl)-N′-(2-ethylphenyl) oxamide in the perovskite precursor solution is 0.5-2 mol: 0.1-4 mg.

12. The method of claim 9, wherein the solvent is selected from the group consisting of dimethylformamide (DMF), dimethyl sulfoxide (DMSO), N-Methyl-2-pyrrolidone (NMP), gamma-butyrolactone (GBL), acetonitrile (ACN), isopropyl alcohol (IPA), and a combination thereof.

13. The method of claim 9, wherein a concentration of Pb²⁺ in the perovskite precursor solution is 0.01 mol/L-10 mol/L.

14. The method of claim 9, wherein the annealing treatment is performed at 50-210° C. for 1 min-30 min.

15. The method of claim 9, wherein the perovskite precursor solution is coated on the substrate through spin coating.

16. The method of claim 15, wherein the spin coating is performed at a rate of 800 rpm-6000 rpm for 5 s-60 s.

17. The method of claim 9, wherein at least one of the mixing, the coating and the annealing treatment is performed at a relative humidity of 0%-50%.

18. The method of claim 9, wherein a thickness of the perovskite active layer is 450 nm-600 nm.

19. A method for preparing a N-(2-ethoxyphenyl)-N′-(2-ethylphenyl) oxamide-doped perovskite solar cell, comprising:
(S100) pre-processing a conductive substrate layer;
(S200) depositing a lower interfacial transport layer on the conductive substrate layer;
(S300) mixing perovskite raw materials and N-(2-ethoxyphenyl)-N′-(2-ethylphenyl) oxamide in a solvent to obtain a perovskite precursor solution; and coating the perovskite precursor solution on the lower interfacial transport layer, followed by annealing treatment to obtain a perovskite active layer;
(S400) depositing an upper interfacial transport layer on the perovskite active layer; and
(S500) forming a metal electrode on the upper interfacial transport layer by vapor deposition to obtain the N-(2-ethoxyphenyl)-N′-(2-ethylphenyl) oxamide-doped perovskite solar cell.
